(19) United States
(12) Patent Application Publication
(10) Pub. No.: US 2011/0102755 A1
(43) Pub. Date: May 5, 2011

(54) METHOD OF MANUFACTURING SEMICONDUCTOR DEVICES AND EXPOSURE APPARATUS

(76) Inventor: Daisuke KAWAMURA, Kanagawa (JP)

(21) Appl. No.: 12/938,992

(22) Filed: Nov. 3, 2010

(30) Foreign Application Priority Data
Nov. 5, 2009 (JP) 2009-254244

(51) Int. Cl. G03B 27/42; H01L 21/66

(52) U.S. Cl. 355/53; 438/14; 257/E21.53

(57) ABSTRACT

According to embodiments, a substrate coated with a resist film is carried into a first pressure adjustment mechanism. Then, a peripheral atmosphere of the substrate is decompressed from an atmospheric pressure by the first pressure adjustment mechanism to measure a physical quantity correlated with an outgassing amount from the substrate. Then, whether to subject the substrate to an EUV exposure is determined based on a measurement result of the physical quantity. If determined not to subject the substrate to the EUV exposure, the substrate is transported into a second pressure adjustment mechanism without the substrate being subjected to the EUV exposure. Then, the substrate is carried out of the second pressure adjustment mechanism.

### CROSS-REFERENCE TO RELATED APPLICATIONS

This application is based upon and claims the benefit of priority from the prior Japanese Patent Application No. 2009-254244, filed on Nov. 5, 2009; the entire contents of which are incorporated herein by reference.

### FIELD

Embodiments described herein relate generally to a method of manufacturing semiconductor devices and an exposure apparatus.

### BACKGROUND

With increasingly finer circuit patterns constituting a semiconductor device, the next-generation lithography technology, namely Extreme Ultra-Violet (EUV) lithography, is being developed. When compared with conventional optical lithography, EUV lithography is different in that masks and optical systems are arranged in a vacuum, substrate coated with a resist film are transported into a vacuum, and masks and optical systems are of the refection mirror type.

In UV lithography and DUV lithography, for example, optical systems, masks, and substrates are each used in an atmosphere of atmospheric pressure. Also in ArF immersion lithography, masks are used under atmospheric pressure and optical systems and substrates are mostly used under atmospheric pressure.

In EUV lithography, on the other hand, reflective optical systems are used in a vacuum and an energy line of very short wavelengths (wavelength: 13.4 nm) is also used and thus, in contrast to optical lithography and EB lithography, there is a problem of degraded reflectance with respect to optical systems or reflective masks. This is because in an EUV exposure apparatus, hydrocarbon, water, and other gases in a vacuum atmosphere where optical systems and the like are arranged adhere to or do damage to the optical systems or reflective masks by being irradiated with EUV light.

Irradiation of resist film on the wafer suvstrate with EUV light can be considered as a cause of generating a gas in a vacuum atmosphere that adheres to or does damage to optical systems or reflective masks. A generally recognized generation mechanism of outgassing from an EUV resist is that a photo acid generator (PAG) in a resist film or a portion of polymer structure is gasified after being irradiated with EUV light, leading to a release of such a gas from inside the resist film. As countermeasures against outgassing generated by such EUV irradiation, improvement of resist material, for example, changes of chemical species of PAG, changes of polymer structure and the like are being studied. When EUV lithography is applied to mass production of semiconductor devices, using a resist material and a process that satisfy predetermined standards in measurement after measuring quantification of some outgassing amount or the degree of damage to optical systems of resist materials and resist processes can be considered.

Outgassing may also be given off from resist film on the substrate or substrates itself on which such films are formed regardless of irradiation with EUV light. Even if the resist material under the resist process that satisfy the standards in prior measurement described above are used, the outgassing amount may increase. When resist film is formed, for example, a residual solvent volume in the resist film may become excessive due to an error in a PAB (Post Apply Bake) process. In such a case, a residual solvent or resist constituents such as PAG and bases in the resist film due to azeotropy when the residual solvent evaporates in a vacuum are released to an excessive degree as outgassing. If a moisture absorbing film such as a silicon oxide film, SOG (spin on glass) film, or SiOC film is formed in a layer below the resist film of a substrate, other types of outgassing may cause a problem. Depending on the history of formation of moisture absorbing films or the atmosphere, water (moisture), water soluble gases (for example, ammonia) and the like are absorbed or adsorbed by moisture absorbing films. If such moisture absorbing films are exposed to a vacuum in an EUV exposure apparatus, water or a water soluble gas may be released into the vacuum. Then, if an outgassing component adheres to a reflective mask or a reflective optical system or reacts with the surface thereof, damage such as a degraded reflectance may be caused. Thus, it is desirable to prevent degradation in reflectance of the optical system and mask.

### BRIEF DESCRIPTION OF THE DRAWINGS

FIG. 1 is a diagram showing a configuration of an EUV exposure apparatus according to a first embodiment.

FIG. 2 is a diagram showing a first configuration example of a pressure adjustment mechanism.

FIG. 3 is a diagram showing a second configuration example of the pressure adjustment mechanism.

FIG. 4 is a diagram illustrating an exposing treatment procedure according to the first embodiment.

FIG. 5 is a diagram illustrating another example of the exposing treatment procedure of an exposure method according to the first embodiment.

FIG. 6 is a diagram showing the configuration of the EUV exposure apparatus according to a second embodiment.

FIG. 7 is a diagram illustrating the exposing treatment procedure of the exposure method according to the second embodiment.

FIG. 8 is a diagram showing the configuration of the pressure adjustment mechanism according to a third embodiment.

FIG. 9 is a diagram showing the configuration of the EUV exposure mechanism according to the third embodiment.

FIG. 10 is a diagram showing the configuration of the pressure adjustment mechanism according to a fourth embodiment.

FIG. 11 is a diagram showing the configuration of the EUV exposure mechanism according to the fourth embodiment.

FIG. 12 is a diagram showing a hardware configuration of a control apparatus.

### DETAILED DESCRIPTION

According to embodiments, a substrate coated with a resist film is carried into a first pressure adjustment mechanism. Then, a peripheral atmosphere of the substrate is decompressed from the atmospheric pressure by the first pressure adjustment mechanism to measure physical quantities correlated with the outgassing amount from the substrate. Then, based on results of the measurement of the physical quantities, whether to subject the substrate to an EUV exposure is determined. If determined not to subject the substrate to an EUV exposure, the substrate is transported into a second pressure adjustment mechanism without subjecting the substrate to an EUV exposure. Then, the peripheral atmosphere of the substrate is compressed to the atmospheric pressure by the second pressure adjustment mechanism before the substrate being carried out of the second pressure adjustment mechanism.

Methods of manufacturing semiconductor devices and exposure apparatuses according to the embodiments will be described below with reference to appended drawings. However, the present invention is not limited by these embodiments.

### First Embodiment

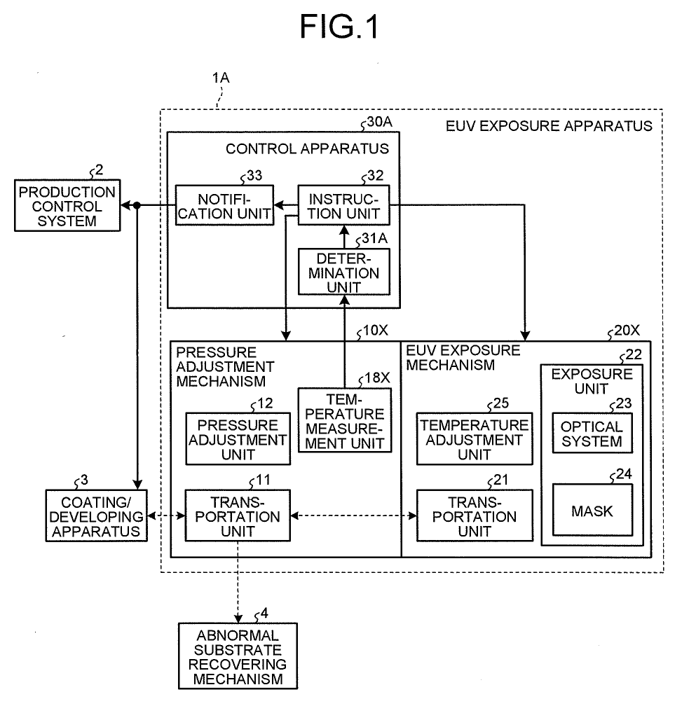

FIG. 1 is a diagram showing the configuration of an EUV exposure apparatus according to a first embodiment. An EUV exposure apparatus 1A is an exposure apparatus used in a lithography process when semiconductor devices are manufactured and performs pattern exposures to a semiconductor substrate (a substrate 5 described later) such as a wafer in a vacuum atmosphere. The EUV exposure apparatus 1A according to the present embodiment performs an exposure to only the normal substrate 5 so that optical systems or reflective masks should not be damaged by excess outgassing generated during EUV lithography. More specifically, before the substrate 5 is exposed, the EUV exposure apparatus 1A measures physical quantities correlated with the outgassing amount that does not necessarily depend on EUV irradiation and originates from the substrate. Then, if the EUV exposure apparatus 1A determines that, based on measured physical quantities, the outgassing amount of the substrate 5 poses a problem, the apparatus 1A takes a predetermined action such as recovering the substrate 5 before being exposed to a vacuum environment linked to a space where an optical system 23 or a mask 24 of an EUV exposure mechanism 20X is present.

The EUV exposure apparatus 1A includes a pressure adjustment mechanism 10X, the EUV exposure mechanism 20X, and a control apparatus 30A. The pressure adjustment mechanism 10X comprises, for example, a load lock chamber, which carries in and carries out the substrate 5 from which a semiconductor device is formed. The pressure adjustment mechanism 10X includes a transportation unit 11, a pressure adjustment unit 12, and a temperature measurement unit 18X.

The transportation unit 11 carries the substrate 5 into the EUV exposure apparatus 1A (the pressure adjustment mechanism 10X). The pressure adjustment unit 12 decompresses the peripheral atmosphere of the substrate 5 using a pressure adjustment function when the substrate 5 is carried into the pressure adjustment mechanism 10X. The pressure adjustment mechanism 10X is linked to the EUV exposure mechanism 20X and the transportation unit 11 transports the substrate 5 to the EUV exposure mechanism 20X in a decompressed state. The pressure adjustment mechanism 10X is shut off from the EUV exposure mechanism 20X in normal operation and only when the substrate 5 is transported between the pressure adjustment mechanism 10X and the EUV exposure mechanism 20X, the pressure adjustment mechanism 10X is opened to the EUV exposure mechanism 20X. The transportation unit 11 stores the substrate 5 transported from the EUV exposure mechanism 20X inside the pressure adjustment mechanism 10X. The pressure adjustment unit 12 compresses the peripheral atmosphere of the substrate 5 to the atmospheric pressure using the pressure adjustment function when the substrate 5 is carried out of the pressure adjustment mechanism 10X. The transportation unit 11 transports the substrate 5 after being compressed to the atmospheric pressure to the outside of the EUV exposure apparatus 1A (to the side of an external apparatus such as a coating/developing apparatus 3 and an abnormal, substrate recovering mechanism 4). The abnormal substrate recovering mechanism 4 is an apparatus that recovers an abnormal substrate determined to be abnormal.

The temperature measurement unit 18X is, for example, a temperature sensor and measures the temperature of the substrate 5 (hereinafter, referred to as a substrate temperature) when the pressure adjustment unit 12 decompresses the peripheral atmosphere of the substrate 5. The temperature measurement unit 18X measures an in-plane distribution of the substrate temperature by measuring the temperature, for example, at a plurality of locations on the plane of the substrate 5. The temperature measurement unit 18X sends the measured substrate temperature to the control apparatus 30A. If the carried-in substrate 5 is more likely to contaminate, for example, the optical system 23 to be described later by outgassing or the like (if the substrate 5 is abnormal), the pressure adjustment mechanism 10X in the present embodiment transports the substrate 5 out of the EUV exposure apparatus 1A without transporting the substrate 5 into the EUV exposure mechanism 20X. If, on the other hand, the carried-in substrate 5 is less likely to contaminate the optical system 23 or the like, the pressure adjustment mechanism 10X transports the substrate 5 into the EUV exposure mechanism 20X. The pressure adjustment mechanism 10X transports the substrate 5 into or out of the EUV exposure mechanism 20X following instructions from the control apparatus 30A.

The EUV exposure mechanism 20X subjects the substrate 5 transported from the pressure adjustment mechanism 10X to an EUV exposure. The EUV exposure mechanism 20X includes a transportation unit 21, an exposure unit 22, and a temperature adjustment unit 25. The transportation unit 21 carries the substrate 5 transported from the pressure adjustment mechanism 10X into the EUV exposure mechanism 20X. The transportation unit 21 transports the substrate 5 to the temperature adjustment unit 25 or the exposure unit 22 and also transports the substrate 5 after exposure to the pressure adjustment mechanism 10X.

The temperature adjustment unit 25 makes substrate temperature adjustments (heating or cooling of the substrate 5) to ensure overlay precision before pattern exposing treatment to the substrate 5. Suppressing deformation accompanying thermal expansion of the substrate 5 is needed to achieve high overlay precision. The exposure unit 22 includes the optical system 23 of the refection type and irradiates the substrate 5 after temperature adjustments with EUV light by using the optical system 23 and the reflective mask 24.

The control apparatus 30A is, for example, a computer that controls the pressure adjustment mechanism 10X and the EUV exposure mechanism 20X and includes a determination unit 31A, an instruction unit 32, and a notification unit 33. The determination unit 31A determines whether the substrate 5 is abnormal based on the substrate temperature sent from the temperature measurement unit 18X. The temperature of the substrate 5 inside the pressure adjustment mechanism 10X is considered to fall due to decompression. The determination unit 31A determines whether the substrate 5 is abnormal based on whether lowering behavior of the substrate temperature from the start of decompression is within a predetermined range. If, for example, the temporal change (rate of change) in the fall of substrate temperature is larger than a predetermined value, the determination unit 31A determines that the substrate 5 is abnormal.

The instruction unit 32 sends instructions concerning, for example, transportation processing of the substrate 5 to the pressure adjustment mechanism 10X and the EUV exposure mechanism 20X based on a determination result of the substrate 5 made by the determination unit 31A. If, for example, the substrate 5 is determined to be abnormal, the instruction unit 32 sends instructions to the pressure adjustment mechanism 10X to carry the substrate 5 out to the outside. More specifically, the instruction unit 32 sends a transportation procedure of the substrate 5 determined to be abnormal (hereinafter, referred to as an abnormal substrate) and pressure adjustment instructions and also transportation instructions (transportation procedure) of the substrate 5 to be processed next (hereinafter, referred to as the next processing substrate) and pressure adjustment instructions to a transportation arm of the transportation unit 11 that transports the substrate 5 and the pressure adjustment unit 12. Transportation instructions for an abnormal substrate include a waiting position of the abnormal substrate and a transportation procedure, and the transportation procedure for the next processing substrate includes pause instructions of the next processing substrate and interruption instructions concerning transportation of the abnormal substrate.

The notification unit 33 is connected to the instruction unit 32, a production control system 2, and the coating/developing apparatus 3 and sends a notification corresponding to instructions sent to the pressure adjustment mechanism 10X or the like by the instruction unit 32 to the production control system 2 and the coating/developing apparatus 3. The production control system 2 is, for example, a computer that manages production control of semiconductor devices and includes a communication function to communicate with various apparatuses (such as the EUV exposure apparatus 1A) that manufacture semiconductor devices.

The coating/developing apparatus 3 is an apparatus that coats the substrate 5 with a resist sensitive to an energy line or develops the resist. The coating/developing apparatus 3 not only forms a resist film by coating the substrate 5 with a resist, but also performs a post applied bake (PAB) process on the resist film. The coating/developing apparatus 3 transports the substrate 5 that has undergone the PAB process to the EUV exposure apparatus 1A. The coating/developing apparatus 3 also performs a post exposure bake (PEB) process on the substrate 5 brought back to the atmospheric pressure after exposing treatment by the EUV exposure apparatus 1A is completed. Accordingly, the coating/developing apparatus 3 forms a latent image corresponding to an EUV light pattern irradiated by the EUV exposure apparatus 1A in the resist film. Further, the coating/developing apparatus 3 performs a development process to remove an unnecessary portion from the resist film where the latent image is formed using a developing solution and rinsing treatment to remove the developing solution used for development process and dissolved resist into the developing solution in order to form a desired resist pattern.

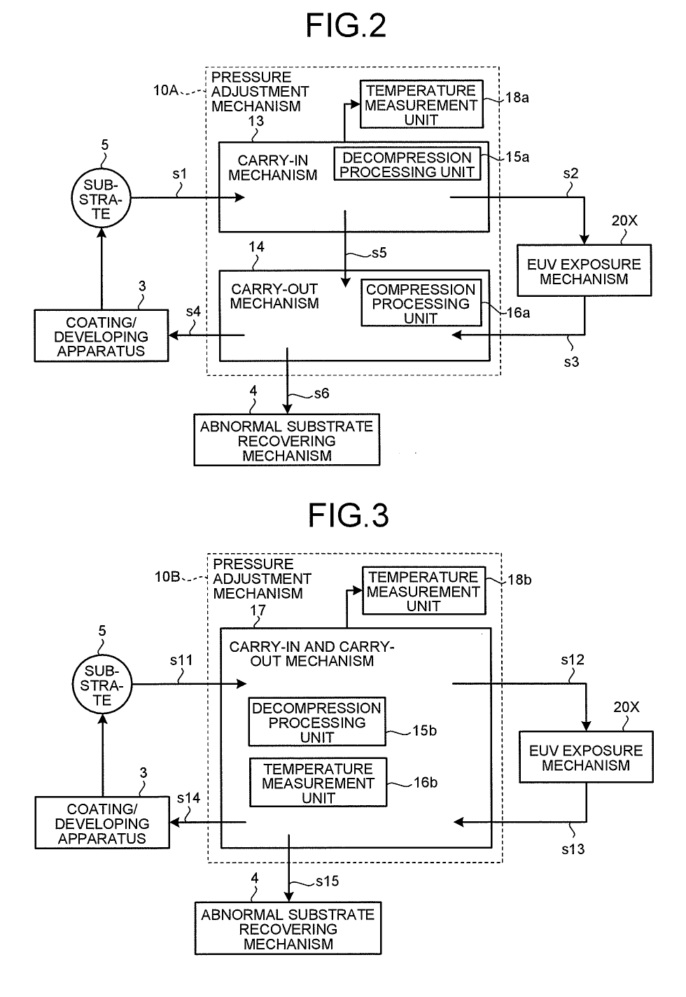

Next, a configuration example of the pressure adjustment mechanism 10X will be described. FIG. 2 is a diagram showing a first configuration example of the pressure adjustment mechanism and FIG. 3 is a diagram showing a second configuration example of the pressure adjustment mechanism. As shown in FIG. 2, a pressure adjustment mechanism 10A, which is the first configuration example of the pressure adjustment mechanism 10X, includes a carry-in mechanism (first pressure adjustment mechanism) 13 to carry the substrate 5 coated with a resist into the EUV exposure mechanism 20X and a carry-out mechanism (second pressure adjustment mechanism) 14 to carry the substrate 5 out of the EUV exposure mechanism 20X. The carry-in mechanism 13 is provided with a decompression processing unit 15a and the carry-out mechanism 14 is provided with a compression processing unit 16a. The decompression processing unit 15a and the compression processing unit 16a here correspond to the pressure adjustment unit 12 shown in FIG. 1. The decompression processing unit 15a performs, among functions of the pressure adjustment unit 12, processing concerning decompression processing and the compression processing unit 16a performs, among functions of the pressure adjustment unit 12, processing concerning compression processing. More specifically, the decompression processing unit 15a decompresses the pressure inside the carry-in mechanism 13 and the compression processing unit 16a compresses the pressure inside the carry-out mechanism 14 to the atmospheric pressure. A temperature measurement unit 18a, which is an example of the temperature measurement unit 18X, measures the substrate temperature inside the carry-in mechanism 13 when the decompression processing unit 15a decompresses the pressure inside the carry-in mechanism 13.

The pressure adjustment mechanism 10A transports the substrate 5 sent from the coating/developing apparatus 3 into the carry-in mechanism 13 (s1). The carry-in mechanism 13 transports the substrate 5 inside the carry-in mechanism 13 to the EUV exposure mechanism 20X (s2) or to the carry-out mechanism 14 (s5). The carry-out mechanism 14 transports the substrate 5 sent from the EUV exposure mechanism 20X into the carry-out mechanism 14 (s3). If the substrate 5 is transported from the carry-in mechanism 13, the carry-out mechanism 14 transports the substrate 5 into the carry-out mechanism 14 (s5). The carry-out mechanism 14 transports the substrate 5 inside the carry-out mechanism 14 to the coating/developing apparatus 3 (s4) or to the abnormal substrate recovering mechanism 4 (s6).

As shown in FIG. 3, a pressure adjustment mechanism 10B, which is the second configuration example of the pressure adjustment mechanism 10X, includes a carrying-in and carrying-out mechanism (first and second pressure adjustment mechanisms) 17 that carries the substrate 5 coated with a resist into the EUV exposure mechanism 20X and also carries the substrate 5 out of the EUV exposure mechanism 20X. In other words, a common mechanism is used for decompression and for compression in the pressure adjustment mechanism 10B and only a transportation system for carrying in and that for carrying out are separately arranged. Incidentally, the carrying-in and carrying-out mechanism 17 may have a common mechanism for carrying-in and carrying-out.

The carrying-in and carrying-out mechanism 17 is provided with a decompression processing unit 15b and a compression processing unit 16b. The decompression processing unit 15b and the compression processing unit 16b here correspond to the pressure adjustment unit 12 shown in FIG. 1. Like the decompression processing unit 15a, the decompression processing unit 15b performs, among functions of the pressure adjustment unit 12, processing concerning decompression processing and, like the compression processing unit 16a, the compression processing unit 16b performs, among functions of the pressure adjustment unit 12, processing concerning compression processing. A temperature measurement unit 18b, which is an example of the temperature measurement unit 18X, measures the substrate temperature inside the carrying-in and carrying-out mechanism 17 when the decompression processing unit 15b decompresses the pressure inside the carrying-in and carrying-out mechanism 17.

The pressure adjustment mechanism 10B transports the substrate 5 sent from the coating/developing apparatus 3 into the carrying-in and carrying-out mechanism 17 (s11). The carrying-in and carrying-out mechanism 17 transports the substrate 5 inside the carrying-in and carrying-out mechanism 17 to the EUV exposure mechanism 20X (s12) or to the coating/developing apparatus 3 (s14) or to the abnormal substrate recovering mechanism 4 (s15). The EUV exposure mechanism 20X transports the substrate 5 into the carrying-in and carrying-out mechanism 17 (s13).

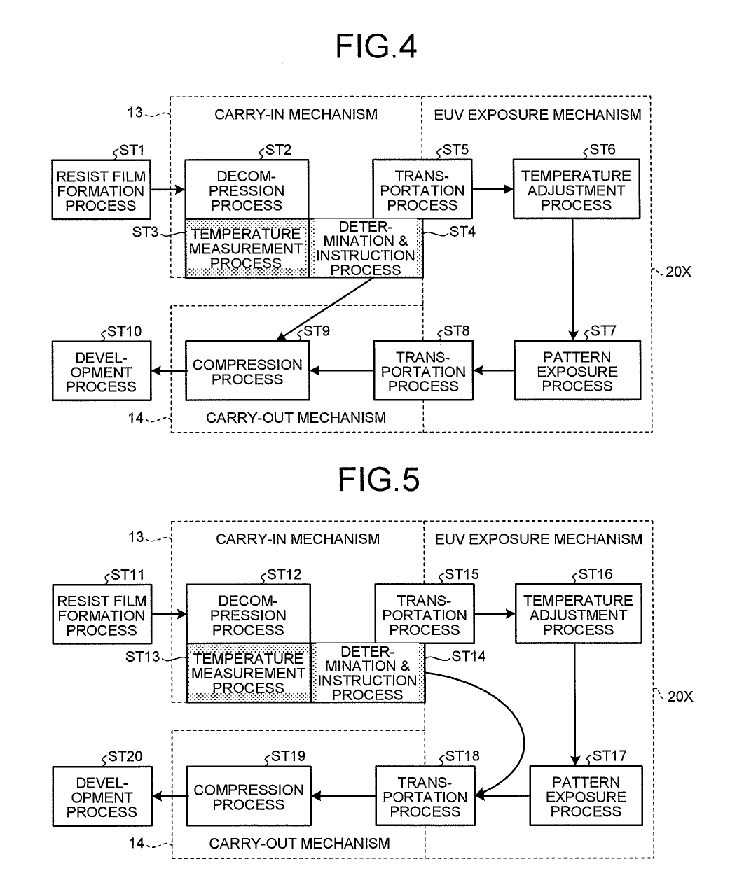

Next, the exposing treatment procedure for the substrate 5 will be described. Here, a case where the pressure adjustment mechanism 10X is the pressure adjustment mechanism 10A will be described. FIG. 4 is a diagram illustrating an exposing treatment procedure according to the first embodiment. The coating/developing apparatus 3 forms a resist film by coating the substrate 5 with a resist (resist film formation process ST1) and also performs the PAB process on the resist film to transport the substrate 5 that has undergone the PAB process to the EUV exposure apparatus 1A.

The carry-in mechanism 13 carries the substrate 5 into the EUV exposure apparatus 1A. The decompression processing unit 15a decompresses the peripheral atmosphere of the substrate 5 (decompression process ST2). The temperature measurement unit 18a measures the substrate temperature when the decompression processing unit 15a decompresses the peripheral atmosphere of the substrate 5 (temperature measurement process ST3) and sends the measured substrate temperature to the determination unit 31A of the control apparatus 30A.

The determination unit 31A determines whether the substrate 5 is abnormal based on the substrate temperature sent from the temperature measurement unit 18a. Further, the instruction unit 32 sends instructions concerning transportation processing of the substrate 5 to the pressure adjustment mechanism 10A based on a determination result of the substrate 5 made by the determination unit 31A. If the substrate 5 is determined not to be abnormal (the case of acceptance), the instruction unit 32 sends instructions to the pressure adjustment mechanism 10A and the EUV exposure mechanism 20X (determination & instruction process ST4) to perform normal exposing treatment. Accordingly, the carry-in mechanism 13 carries the substrate 5 into the EUV exposure mechanism 20X (transportation process ST5).

In the EUV exposure mechanism 20X, the temperature adjustment unit 25 makes substrate temperature adjustments to ensure overlay precision before pattern exposing treatment to the substrate 5 (temperature adjustment process ST6). After substrate temperature adjustments or partially during the processing, predetermined measurement (for example, overlay mark measurement) of the substrate 5 is made. Then, the exposure unit 22 irradiates the resist film after temperature adjustment with EUV light patterned by using the optical system 23 and the mask 24 (pattern exposure process ST7).

Subsequently, the carry-out mechanism 14 transports the substrate 5 into the carry-out mechanism 14 (transportation process ST8). The compression processing unit 16a compresses the peripheral atmosphere of the substrate 5 to the atmospheric pressure (compression process ST9). The carry-out mechanism 14 transports the substrate 5 after the compression to the atmospheric pressure to the coating/developing apparatus 3.

The coating/developing apparatus 3 forms a latent image corresponding to an EUV light pattern in the resist film by performing the PEB process on the substrate 5 whose exposing treatment by the EUV exposure apparatus 1A is completed, if necessary. Further, the coating/developing apparatus 3 removes an unnecessary portion from the resist film where the latent image is formed using a developing solution (development process ST10) and performs rinsing treatment to remove the developing solution used for development process and dissolved resist into the developing solution. Accordingly, a desired resist pattern is formed on the substrate 5. Subsequently, the substrate 5 is processed (for example, etched) using the resist pattern or a pattern formed from the resist pattern as a processing mask.

Thus, if the substrate 5 is not abnormal, the substrate 5 is transported from the coating/developing apparatus 3 to the carry-in mechanism 13 (s1) and from the carry-in mechanism 13 to the EUV exposure mechanism 20X (s2). Further, the substrate 5 is transported from the EUV exposure mechanism 20X to the carry-out mechanism 14 (s3) and from the carry-out mechanism 14 to the coating/developing apparatus 3 (s4).

If, on the other hand, the substrate 5 is determined to be abnormal (the case of rejection), the instruction unit 32 sends instructions to the pressure adjustment mechanism 10A and the EUV exposure mechanism 20X to transport the substrate 5 to the outside. More specifically, the instruction unit 32 sends instructions to the pressure adjustment mechanism 10A and the EUV exposure mechanism 20X to transport the substrate 5 from the carry-in mechanism 13 to the coating/developing apparatus 3 via the carry-out mechanism 14. The instruction unit 32 determines priorities of transportation (ejection) of each of the substrate 5 such as the substrate 5 determined to be abnormal, the substrate 5 transported into the EUV exposure mechanism 20X before the substrate 5 determined to be abnormal and in the process of pattern exposure, and the substrate 5 waiting to be exposed such as in the process of temperature adjustment or measurement before pattern exposure, and sends instructions in accordance with a determination result to the pressure adjustment mechanism 10X and the EUV exposure mechanism 20X. Subsequently, the decompression processing unit 15a performs a stop operation of the decompression processing and the carry-in mechanism 13 transports the abnormal substrate to the carry-out mechanism 14.

Then, the compression processing unit 16a compresses the peripheral atmosphere of the substrate 5 to the atmospheric pressure (compression process ST9). The carry-out mechanism 14 transports the substrate 5 after the compression to the atmospheric pressure to the coating/developing apparatus 3.

If the substrate 5 is determined to be abnormal, the notification unit 33 sends the fact that the substrate 5 has been determined to be abnormal, information to identify the abnormal substrate (such as a wafer number), adjustment instructions for the cycle time on the side of the coating/developing apparatus 3 accompanying the transportation of the abnormal substrate and the like as notification information to the production control system 2 and the coating/developing apparatus 3. If the abnormal substrate should be carried out prior to the substrate 5 which have been carried into the EUV exposure apparatus 1A earlier, the notification unit 33 may send instructions to the coating/developing apparatus 3 so that the position (slot number) in a substrate carrying case (FOUP) of the coating/developing apparatus 3 to store the abnormal substrate remains the same as that when no abnormal substrate is detected. The coating/developing apparatus 3 sends the substrate 5 determined to be abnormal to another processing apparatus (such as an inspection apparatus) without performing the development process or the like of the substrate 5. The coating/developing apparatus may perform the same development process intended for the substrate 5 determined not to be abnormal also on the substrate 5 determined to be abnormal. Other processing performed on the substrate 5 determined to be abnormal includes inspection processing and re-work processing of the substrate 5. As the inspection processing, inspection of a coated film by an optical particle inspection apparatus or optical microscope to check the state of resist coating can be considered. The re-work processing is re-work of the lithography process. The re-work processing includes a removal process of a resist film formed by the coating/developing apparatus to perform a similar EUV exposure process again. A removal process of a lower-layer film below the resist film followed by re-forming the lower-layer film is performed as necessary.

If the substrate 5 is determined to be abnormal, the instruction unit 32 may send instructions to the pressure adjustment mechanism 10A so that the substrate 5 is transported from the carry-in mechanism 13 to the abnormal substrate recovering mechanism 4 via the carry-out mechanism 14. In this case, the carry-in mechanism 13 transports the substrate 5 to the carry-out mechanism 14.

Then, the compression processing unit 16a compresses the peripheral atmosphere of the substrate 5 to the atmospheric pressure (compression process ST9). The carry-out mechanism 14 transports the substrate 5 after the compression to the atmospheric pressure to the abnormal substrate recovering mechanism 4.

Thus, if the substrate 5 is abnormal, the substrate 5 is transported from the coating/developing apparatus 3 to the carry-in mechanism 13 (s1) and from the carry-in mechanism 13 to the carry-out mechanism 14 (s5) and then, the substrate 5 is transported from the carry-out mechanism 14 to the coating/developing apparatus 3 (s4) or to the abnormal substrate recovering mechanism 4 (s6).

If the pressure adjustment mechanism 10X is the pressure adjustment mechanism 10B and the substrate 5 is not abnormal, the substrate 5 is transported from the coating/developing apparatus 3 to the carrying-in and carrying-out mechanism 17 (s11) and from the carrying-in and carrying-out mechanism 17 to the EUV exposure mechanism 20X (s12). Further, the substrate 5 is transported from the EUV exposure mechanism 20X to the carrying-in and carrying-out mechanism 17 (s13) and from the carrying-in and carrying-out mechanism 17 to the coating/developing apparatus 3 (s14).

If the pressure adjustment mechanism 10X is the pressure adjustment mechanism 10B and the substrate 5 is abnormal, the substrate 5 is transported from the coating/developing apparatus 3 to the carrying-in and carrying-out mechanism 17 (s11) and then, from the carrying-in and carrying-out mechanism 17 to the coating/developing apparatus 3 (s14) or to the abnormal substrate recovering mechanism 4 (s15).

The exposing treatment procedure of the substrate 5 is not limited to the exposing treatment procedure shown in FIG. 4 and may be another exposing treatment procedure. FIG. 5 is a diagram illustrating another example of the exposing treatment procedure according to the first embodiment. Here, a case where the pressure adjustment mechanism 10X is the pressure adjustment mechanism 10A will be described. A description of exposing treatment procedures shown in FIG. 5 that are the same treatment procedures as those shown in FIG. 4 is not repeated.

If the substrate 5 is not abnormal, exposures of the substrate 5 and the like are performed according to the same treatment procedure as the exposing treatment procedure illustrated in FIG. 4. Here, the treatment procedure when the substrate 5 is determined to be abnormal will be described.

Of the exposing treatment procedures shown in FIG. 5, a resist film formation process ST11, a decompression process ST12, a temperature measurement process ST13, a temperature adjustment process ST16, and a pattern exposure process ST17 are the same processes as the resist film formation process ST1, the decompression process ST2, the temperature measurement process ST3, the temperature adjustment process ST6, and the pattern exposure process ST7, respectively.

The determination unit 31A determines, as a determination & instruction process, whether the substrate 5 is abnormal based on the temperature substrate sent from the temperature measurement unit 18a. Further, the instruction unit 32 sends instructions concerning transportation processing of the substrate 5 to the pressure adjustment mechanism 10A based on a determination result of the substrate 5 made by the determination unit 31A.

If the substrate 5 is determined to be abnormal, the instruction unit 32 sends instructions to the pressure adjustment mechanism 10X and the EUV exposure mechanism 20X to transport the substrate 5 to the outside. More specifically, the instruction unit 32 sends instructions to the pressure adjustment mechanism 10A and the EUV exposure mechanism 20X to transport the substrate 5 from the carry-in mechanism 13 to the coating/developing apparatus 3 via EUV exposure mechanism 20X and the carry-out mechanism 14 (determination & instruction process ST14). Accordingly, the carry-in mechanism 13 causes the abnormal substrate to wait inside the carry-in mechanism 13 for a predetermined time and then, transports the abnormal substrate to the EUV exposure mechanism 20X (transportation process ST15).

The abnormal substrate is transported to the carry-out mechanism 14 (transportation process ST18) without either making substrate temperature adjustments by the temperature adjustment unit 25 (temperature adjustment process ST16) or performing irradiation with EUV light by the exposure unit 22 (pattern exposure process ST17) inside the EUV exposure mechanism 20X. In other words, if the substrate 5 is determined to be abnormal, the abnormal substrate is transported to the carry-out mechanism 14 by being caused to pass through the EUV exposure mechanism 20X with the minimum stroke and/or minimum duration. Incidentally, if the substrate 5 is abnormal, the substrate 5 may be transported from the EUV exposure mechanism 20 to the carry-out mechanism 14 after substrate temperature adjustments made by the temperature adjustment unit 25 (temperature adjustment process ST16).

Subsequently, the compression processing unit 16a of the carry-out mechanism 14 compresses the peripheral atmosphere of the substrate 5 to the atmospheric pressure (compression process ST19). Then, the notification unit 33 sends the fact that the substrate 5 has been determined to be abnormal and information to identify the abnormal substrate to the production control system 2 and the coating/developing apparatus 3. The coating/developing apparatus 3 sends the abnormal substrate to another processing apparatus without performing a development process of the substrate 5 determined to be abnormal.

If the substrate 5 is determined to be abnormal, the instruction unit 32 may send instructions to the pressure adjustment mechanism 10A and the EUV exposure mechanism 20X so that the substrate 5 is transported to the abnormal substrate recovering mechanism 4 via the EUV exposure mechanism 20X and the carry-out mechanism 14.

Thus, if the substrate 5 is abnormal, the substrate 5 is transported from the coating/developing apparatus 3 to the carry-in mechanism 13 (s1) and from the carry-in mechanism 13 to the EUV exposure mechanism 20X (s2). Further, the substrate 5 is transported from the EUV exposure mechanism 20X to the carry-out mechanism 14 (s3) and from the carry-out mechanism 14 to the coating/developing apparatus 3 (s4).

If the pressure adjustment mechanism 10X is the pressure adjustment mechanism 10B and the substrate 5 is abnormal, the substrate 5 is transported from the coating/developing apparatus 3 to the carrying-in and carrying-out mechanism 17 (s11) and from the carrying-in and carrying-out mechanism 17 to the EUV exposure mechanism 20X (s12). Further, the substrate 5 is transported from the EUV exposure mechanism 20X to the carrying-in and carrying-out mechanism 17 (s13) and from the carrying-in and carrying-out mechanism 17 to the coating/developing apparatus 3 (s14).

Criteria for determining whether the substrate 5 is abnormal may be changed for each exposing treatment process (each layer of the circuit-devices) of, for example, a wafer process. This is because, if the configuration of the substrate 5 is different in each layer, the amount of outgassing emission and an influence thereof will change.

In the present embodiment, the substrate 5 is determined to be abnormal if, for example, the temporal change in the fall of substrate temperature is larger than a predetermined value, but whether the substrate 5 is abnormal may be determined based on other criteria. For example, if the substrate 5 is abnormal, water or the like emerges from inside the abnormal substrate and the temperature of the abnormal substrate falls rapidly when compared with a normal substrate due to heat of vaporization of water that emerged. Thus, the determination unit 31A may determine that the substrate 5 is abnormal if the substrate temperature after a predetermined time passes from the start of decompression is lower than a threshold.

If the temperature of the abnormal substrate falls more rapidly than normal, heating treatment may be needed for the substrate 5 to cause the substrate 5 to reach a desired temperature. Thus, if the temperature of the abnormal substrate falls more rapidly than normal, a longer time may be needed to reach a desired substrate temperature than normal. Therefore, if the time needed for the substrate temperature to reach a predetermined temperature is longer than a predetermined time, the determination unit 31A may determine that the substrate 5 is abnormal.

In addition to the processing on the abnormal substrate described above, predetermined inspection processing may be performed on the optical system 23, the mask 24, and the pressure adjustment mechanism 10X if necessary. As inspection processing on the pressure adjustment mechanism 10X, the number of particles passing through the pressure adjustment mechanism 10X before being stuck to the substrate 5 may be inspected. If the result of inspection processing fails, a failed location may be cleaned. As cleaning of the optical system 23 or the mask 24, for example, such a failed location may be irradiated with active hydrogen, active oxygen, or UV-light. Or, the cleaning process may be a combination of, for example, a repetition of decompression and compression in the pressure adjustment mechanism 10X, maintenance of a decompressed state, burning of a decompressed chamber, and solvent cleaning inside the decompressed chamber.

In the present embodiment, a case where an abnormal substrate is transported from the carry-in mechanism 13 to the carry-out mechanism 14 after a stop operation of the decompression processing is performed has been described, but a stop operation of the decompression processing and transportation of an abnormal substrate from the carry-in mechanism 13 to the carry-out mechanism 14 may be performed simultaneously.

Also in the present embodiment, when an abnormal substrate arises, the abnormal substrate is transported out of the pressure adjustment mechanism 10X on various transportation routes, but the instruction unit 32 may make a selection of which transportation route to use based on the degree of abnormality of the abnormal substrate. For example, if the degree of abnormality is greater that a predetermined value, the abnormal substrate is transported out of the pressure adjustment mechanism 10X on the transportation route illustrated in FIG. 4. If the degree of abnormality is smaller that the predetermined value, the abnormal substrate is transported out of the pressure adjustment mechanism 10X on the transportation route illustrated in FIG. 5.

Thus, whether the substrate 5 is abnormal is determined based on the substrate temperature when the pressure adjustment unit 12 decompresses the peripheral atmosphere of the substrate 5, and therefore, whether the substrate 5 is abnormal can be determined correctly and easily.

If the substrate 5 is determined to be abnormal, decompression processing is stopped and thus, contamination of the carry-in mechanism 13 due to outgassing (particularly, a residual solvent and resist constituents by azeotropy) discharged from the abnormal substrate can be suppressed.

If the abnormal substrate is carried out of the EUV exposure mechanism 20X without being transported into the EUV exposure mechanism 20X, outgassing discharged from the abnormal substrate can be prevented from being brought thereinto. While the carry-in mechanism 13 is decompressed, the pressure adjustment mechanism 10X is shut off from the EUV exposure mechanism 20X. Thus, the amount of substance (such as a gas that could damage the optical system 23) that is generated inside the carry-in mechanism 13 when decompression is carried out on the substrate 5 for the first time and is penetrating into the EUV exposure mechanism 20X can be minimized. Moreover, since many kinds of substance that could damage the optical system 23 or the like are generated particularly in the initial stage of decompression and thus, if the abnormal substrate is not transported into the EUV exposure mechanism 20X, contamination of the optical system 23, the mask 24 and the like by outgassing can efficiently be prevented. Besides, EUV exposures cause higher running costs of exposure operation and thus, running costs can be reduced by omitting wasteful exposure.

When the abnormal substrate is carried out of the EUV exposure mechanism 20X without exposing treatment provided thereto after being carried into the EUV exposure mechanism 20X, outgassing resulting from pattern exposure can be prevented and thus, contamination of the optical system 23 and the like can be prevented.

The abnormal substrate is transported to the EUV exposure mechanism 20X after being caused to wait for a predetermined time inside the carry-in mechanism 13 and thus, the outgassing amount generated inside the EUV exposure mechanism 20X can be reduced.

If a dimension error or the like is detected in the abnormal substrate, subsequent processing such as a treatment process is not performed and thus, wasteful subsequent processing on the abnormal substrate can be reduced so that losses due to wasteful subsequent processing can be reduced. If a substrate is abnormal, but the whole surface of the substrate or a predetermined chip thereof is free from abnormality, subsequent processing is performed and thus, losses due to an occurrence of abnormal substrate can be reduced.

When an abnormal substrate arises, predetermined inspection processing is performed on the optical system 23, the mask 24, and the pressure adjustment mechanism 10X and thus, it becomes possible to guarantee long stability of the EUV exposure apparatus 1A as well as maintain yields due to stable operation of the EUV exposure apparatus 1A and suppress deterioration of the availability ratio due to repairs of apparatus or the like.

The temperature measurement unit 18X and a temperature measurement unit 26Y measure an in-plane distribution of the substrate temperature. Thus, a drop in temperature of the substrate 5 or a delay in temperature adjustment in the temperature adjustment unit 25 during a decompression process due to a residual solvent on the substrate 5 or heat of cooling of absorbed water can be detected with high precision on the plane of the substrate 5.

If the degree of abnormality is low even if the substrate 5 is an abnormal substrate, normal expositing treatment may be provided to the abnormal substrate in combination with inspection of the optical system 23, the mask 24, and the pressure adjustment mechanism 10X. In this case, the notification unit 33 generates a flag indicating an error on the abnormal substrate and sends the flag to the production control system 2 and the coating/developing apparatus 3. Then, after a resist pattern is formed on the abnormal substrate, a re-work process is performed on the abnormal substrate. The re-work process here includes removal of the resist pattern formed on the abnormal substrate and recoating of the abnormal substrate with a resist.

Predetermined inspection processing may be performed on the abnormal substrate after a resist pattern is formed on the abnormal substrate and/or pattern processing in a predetermined stage is performed. As the inspection processing, for example, whether the whole surface of the substrate 5 or a predetermined chip thereof is abnormal (such as a dimension error) is inspected. If no error is detected in the inspection process, the subsequent treatment process is performed. If an error is detected, the re-work process is performed or the abnormal substrate is discarded.

Thus, according to the first embodiment, the substrate 5 whose abnormal temperature in the pressure adjustment mechanism 10X has been detected is not subjected to EUV exposure in a vacuum environment and therefore, degradation in reflectance of the optical system 23 and the mask 24 used for EUV exposure can be prevented.

### Second Embodiment

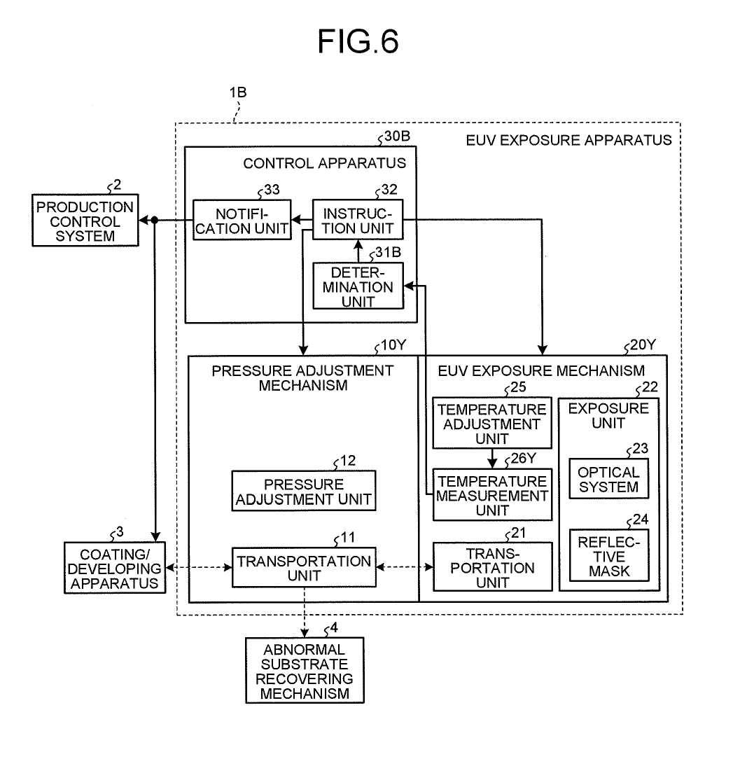

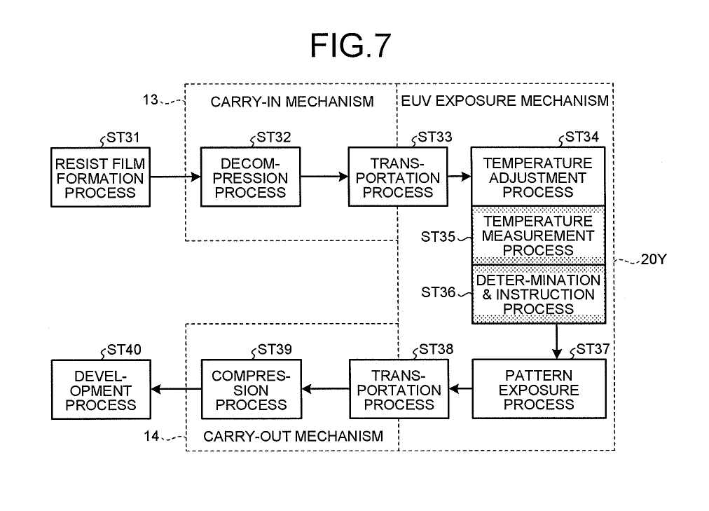

Next, a second embodiment of the present invention will be described with reference to FIGS. 6 and 7. In the second embodiment, the temperature of the substrate 5 in an EUV exposure mechanism 20Y to be described later is measured and determines whether the substrate 5 is abnormal.

FIG. 6 is a diagram showing the configuration of the EUV exposure apparatus according to the second embodiment. The same numerals are attached to components, among components in FIG. 6, having the same function as those of the EUV exposure mechanism 1A in the first embodiment shown in FIG. 1 to avoid a duplicate description.

An EUV exposure mechanism 1B includes a pressure adjustment mechanism 10Y, the EUV exposure mechanism 20Y, and a control apparatus 30B. The pressure adjustment mechanism 10Y includes the transportation unit 11 and the pressure adjustment unit 12. The EUV exposure mechanism 20Y includes, in addition to the transportation unit 21, the exposure unit 22, and the temperature adjustment unit 25, a temperature measurement unit (temperature adjustment unit) 26Y. The temperature measurement unit 26Y is arranged at a predetermined distance apart from the exposure unit 22 and measures the substrate temperature when the temperature adjustment unit 25 adjusts the temperature of the substrate 5. The temperature measurement unit 26Y measures an in-plane distribution of the substrate temperature by measuring the temperature, for example, at a plurality of locations on the plane of the substrate 5. The temperature measurement unit 26Y sends the measured substrate temperature to the control apparatus 30B.

The control apparatus 30B includes, in addition to the instruction unit 32 and the notification unit 33, a determination unit 31B. Like the determination unit 31A, the determination unit 31B determines whether the substrate 5 is abnormal based on the substrate temperature sent from the temperature measurement unit 26Y, and sends a determination result to the instruction unit 32. The configuration example of the pressure adjustment mechanism 10Y is almost the same as that of the pressure adjustment mechanism 10A/10B and is different from the pressure adjustment mechanism 10A/10B in that the pressure adjustment mechanism 10Y does not have the temperature measurement unit 18a/18b.

Next, the exposing treatment procedure of the substrate 5 will be described. FIG. 7 is a diagram illustrating the exposing treatment procedure of the exposure method according to the second embodiment. Here, a case where the pressure adjustment mechanism 10Y includes, like the pressure adjustment mechanism 10A, the carry-in mechanism 13 and the carry-out mechanism 14 will be described. A description of exposing treatment procedures shown in FIG. 7 that are the same treatment procedures as those shown in FIG. 4 will not be repeated.

Of the exposing treatment procedures shown in FIG. 7, a resist film formation process ST31, a decompression process ST32, and a transportation process ST33 are the same processes as the resist film formation process ST1, the decompression process ST2, and the transportation process ST5, respectively. Thus, in the present embodiment, the substrate 5 is transported from the carry-in mechanism 13 into the EUV exposure mechanism 20Y without the temperature of the substrate 5 being measured in the carry-in mechanism 13.

Subsequently, like the temperature adjustment process ST6 illustrated in FIG. 4, the temperature adjustment unit 25 makes temperature adjustments of the substrate 5 (temperature adjustment process ST34). At this point, the temperature measurement unit 26Y measures the substrate temperature when the temperature adjustment unit 25 makes temperature adjustments of the substrate 5 (temperature measurement process ST35) and sends the measured substrate temperature to the determination unit 31B of the control apparatus 30B.

Like the determination unit 31A in FIG. 1, the determination unit 31B determines whether the substrate 5 is abnormal based on the substrate temperature sent from the temperature measurement unit 26Y. Further, the instruction unit 32 sends instructions concerning transportation processing of the substrate 5 to the pressure adjustment mechanism 10Y and the EUV exposure mechanism 20Y based on a determination result of the substrate 5 made by the determination unit 31B.

If the substrate 5 is determined not to be abnormal, the instruction unit 32 sends instructions to the pressure adjustment mechanism 10Y and the EUV exposure mechanism 20Y to provide normal expositing treatment (determination & instruction process ST36). Accordingly, as processes similar to the pattern exposure process ST7 to the development process ST10 illustrated in FIG. 4, a pattern exposure process ST37, a transportation process ST38, a compression process ST39, and a development process ST40 are performed in the EUV exposure mechanism 20Y.

If, on the other hand, the substrate 5 is determined to be abnormal, the instruction unit 32 sends instructions to the pressure adjustment mechanism 10Y and the EUV exposure mechanism 20Y to transport the substrate 5 without providing expositing treatment (determination & instruction process ST36). Accordingly, as processes similar to the pattern transportation process ST8 to the development process ST10 illustrated in FIG. 4, the transportation process ST38, the compression process ST39, and the development process ST40 are performed in the EUV exposure mechanism 20Y.

Thus, in the present embodiment, the substrate 5 is transported from the coating/developing apparatus 3 to the carry-in mechanism 13 (s1) and from the carry-in mechanism 13 to the EUV exposure mechanism 20Y (s2) regardless of whether the substrate 5 is abnormal. Then, if the substrate 5 is abnormal, no pattern exposure is performed to the substrate 5. If the substrate 5 is not abnormal, a pattern exposure is performed to the substrate 5. Then, the substrate 5 is transported from the EUV exposure mechanism 20Y to the carry-out mechanism 14 (s3) and from the carry-out mechanism 14 to the coating/developing apparatus 3 (s4).

Even if the pressure adjustment mechanism 10Y includes, like the pressure adjustment mechanism 10B, the carrying-in and carrying-out mechanism 17, the substrate 5 is transported and exposed according to the same processing procedure as that illustrated in FIG. 7. That is, the temperature measurement process ST35 and the determination & instruction process ST36 are performed between the temperature adjustment process ST16 and the pattern exposure process ST17 illustrated in FIG. 5.

Thus, according to the second embodiment, the temperature of the substrate 5 is measured while the temperature adjustment unit 25 adjusts the temperature of the substrate 5, which makes the temperature measurement unit of the pressure adjustment mechanism 10Y unnecessary. The configuration of the pressure adjustment mechanism 10Y is thereby made simpler. Therefore, the EUV exposure mechanism 1B with a simple configuration can prevent degradation in reflectance of the optical system 23 and the mask 24 used for EUV exposure. Moreover, the substrate 5 is transported out of the EUV exposure mechanism 20Y without being subjected to EUV exposure and thus, outgassing during EUV exposure can be suppressed. Furthermore, the temperature measurement unit 26Y is arranged at a predetermined distance apart from the exposure unit 22 and thus, degradation in reflectance of the optical system 23 and the mask 24 used for EUV exposure can be prevented.

### Third Embodiment

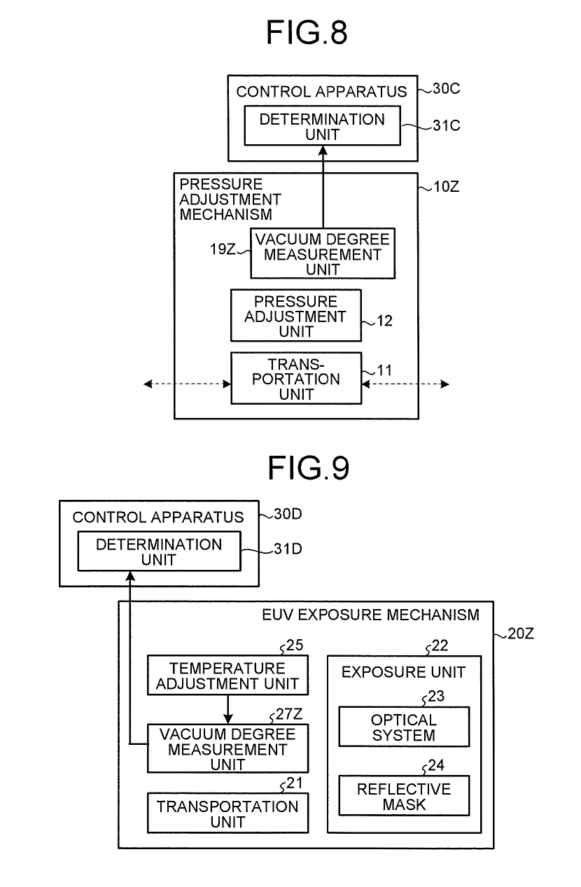

Next, a third embodiment of the present invention will be described with reference to FIGS. 8 and 9. In the third embodiment, the degree of vacuum (pressure) of the peripheral atmosphere of the substrate 5 inside a pressure adjustment mechanism 10Z or an EUV exposure mechanism 20Z to be described later is measured to determine whether the substrate 5 is abnormal based on a measurement result of the degree of vacuum.

FIG. 8 is a diagram showing the configuration of the pressure adjustment mechanism according to the third embodiment. The same numerals are attached to components, among components in FIG. 8, having the same function as those of the pressure adjustment mechanism 10X or the control apparatus 30A shown in FIG. 1 to avoid a duplicate description.

The configuration example of the pressure adjustment mechanism 10Z is almost the same as that of the pressure adjustment mechanism 10A/10B. The pressure adjustment mechanism 10Z is different from the pressure adjustment mechanism 10A/10B in that the pressure adjustment mechanism 10Z does not have the temperature measurement unit 18a/18b and includes a vacuum degree measurement unit 19Z. That is, the pressure adjustment mechanism 10Z includes, in addition to the transportation unit 11 and the pressure adjustment unit 12, the vacuum degree measurement unit 19Z. The vacuum degree measurement unit 19Z measures the degree of vacuum of the peripheral atmosphere (inside the carry-in mechanism 13 or the carrying-in and carrying-out mechanism 17) of the substrate 5 when the pressure adjustment unit 12 decompresses the peripheral atmosphere of the substrate 5. The vacuum degree measurement unit 19Z sends the measured degree of vacuum to the control apparatus 30C.

The control apparatus 30C includes, in addition to the instruction unit 32 and the notification unit 33, a determination unit 31C. In FIG. 8, the instruction unit 32 and the notification unit 33 is not illustrated. The determination unit 31C determines whether the substrate 5 is abnormal based on the degree of vacuum sent from the vacuum degree measurement unit 19Z.

If there is a residual solvent on the substrate 5 or absorbed water on the substrate 5, a delay in decreased pressure or deterioration of the achieved degree of vacuum during decompression may result. Therefore, the determination unit 31C determines whether the substrate 5 is abnormal based on whether lowering behavior of the degree of vacuum from the start of decompression is within a predetermined range. If the outgassing amount from the substrate 5 during decompression is larger than a predetermined amount, the speed of decompression decreases or a time needed to reach a predetermined degree of vacuum increases. For example, if the temporal change (rate of change) when the degree of vacuum falls is smaller than a predetermined value, the determination unit 31C determines that the substrate 5 is abnormal. The determination unit 31C may also determine that the substrate 5 is abnormal if the degree of vacuum after a predetermined time passes from the start of decompression is higher than a threshold. The determination unit 31C may also determine that the substrate 5 is abnormal if the time needed for the degree of vacuum to reach a predetermined value is longer than a predetermined time. The determination unit 31C sends a determination result whether the substrate 5 is abnormal to the instruction unit 32.

The degree of vacuum of the peripheral atmosphere of the substrate 5 may be measured in the EUV exposure mechanism 20Z, instead of the pressure adjustment mechanism 10X. FIG. 9 is a diagram showing the configuration of the EUV exposure apparatus according to the third embodiment. The same numerals are attached to components, among components in FIG. 9, having the same function as those of the pressure adjustment mechanism 10X or the control apparatus 30A shown in FIG. 1 to avoid a duplicate description.

The EUV exposure mechanism 20Z includes, in addition to the transportation unit 21, the exposure unit 22, and the temperature adjustment unit 25, a vacuum degree measurement unit 27Z. The vacuum degree measurement unit 27Z measures the degree of vacuum of the peripheral atmosphere of the substrate 5 while the temperature adjustment unit 25 adjusts the temperature of the substrate 5. The vacuum degree measurement unit 19Z sends the measured degree of vacuum to a control apparatus 30D.

The control apparatus 30D includes, in addition to the instruction unit 32 and the notification unit 33, a determination unit 31D. In FIG. 9, the instruction unit 32 and the notification unit 33 is not illustrated. The determination unit 31D determines, like the determination unit 31C, whether the substrate 5 is abnormal based on the degree of vacuum sent from the vacuum degree measurement unit 19Z and sends a determination result to the instruction unit 32.

Like the first embodiment or the second embodiment, the substrate 5 whose abnormal degree of vacuum has been detected in the pressure adjustment mechanism 10Z or the EUV exposure mechanism 20Z is transported to the coating/developing apparatus 3 or the abnormal substrate recovering mechanism 4 without being subjected to EUV exposure in a vacuum environment.

Thus, whether the substrate 5 is abnormal is determined based on the degree of vacuum when the pressure adjustment unit 12 decompresses the peripheral atmosphere of the substrate 5, and therefore, whether the substrate 5 is abnormal can be determined correctly and easily. Thus, according to the third embodiment, the substrate 5 whose abnormal degree of vacuum has been detected in the pressure adjustment mechanism 10Z or the EUV exposure mechanism 20Z is not subjected to EUV exposure in a vacuum environment, and therefore, degradation in reflectance of the optical system 23 and the mask 24 used for EUV exposure can be prevented.

### Fourth Embodiment

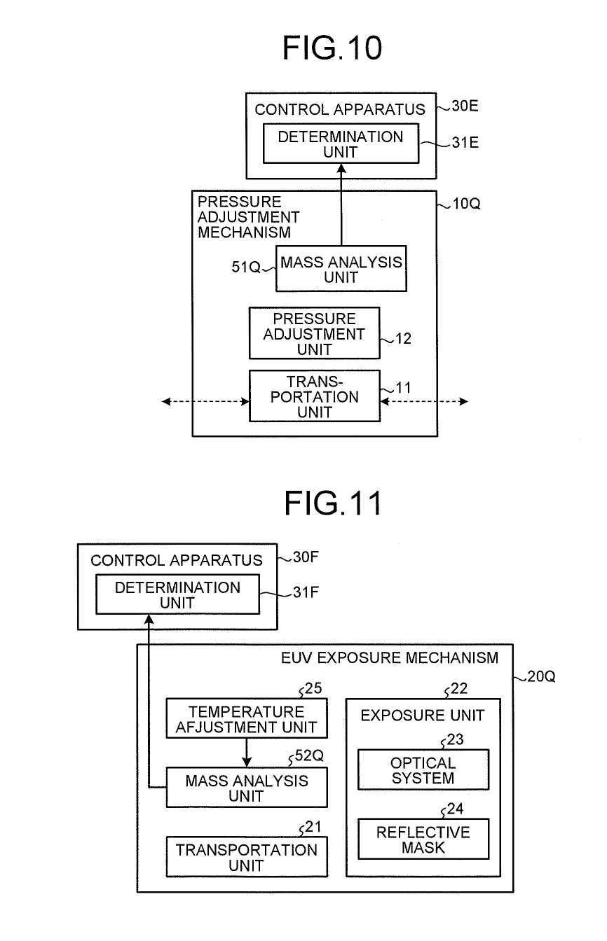

Next, a fourth embodiment of the present invention will be described with reference to FIGS. 10 and 11. In the fourth embodiment, a mass analysis of the substrate 5 is conducted inside a pressure adjustment mechanism 10Q or an EUV exposure mechanism 20Q to be described later to determine whether the substrate 5 is abnormal based on a mass analysis result.

FIG. 10 is a diagram showing the configuration of the pressure adjustment mechanism according to the fourth embodiment. The same numerals are attached to components, among components in FIG. 10, having the same function as those of the pressure adjustment mechanism 10X or the control apparatus 30A shown in FIG. 1 to avoid a duplicate description.

The configuration example of the pressure adjustment mechanism 10Q is almost the same as that of the pressure adjustment mechanism 10A/10B. The pressure adjustment mechanism 10Q is different from the pressure adjustment mechanism 10A/10B in that the pressure adjustment mechanism 10Q does not have the temperature measurement unit 18a/18b and includes a mass analysis unit 51Q. That is, the pressure adjustment mechanism 10Q includes, in addition to the transportation unit 11 and the pressure adjustment unit 12, the mass analysis unit 51Q.

The mass analysis unit 51Q conducts a mass analysis (qualitative/quantitative analysis) inside a chamber (inside the carry-in mechanism 13 or the carrying-in and carrying-out mechanism 17) of the pressure adjustment mechanism 10Q when the pressure adjustment unit 12 decompresses the peripheral atmosphere of the substrate 5. The mass analysis unit 51Q includes, for example, as a gaseous phase analysis function inside the pressure adjustment mechanism 10Q, a mass analysis means such as Q-mass (quadruple mass analysis).

In the present embodiment, chemical species to be detected and fragments are identified in advance to conduct a mass analysis inside the pressure adjustment mechanism 10Q. The mass analysis unit 51Q conducts a mass analysis at least while decompression processing is performed on the substrate 5 to detect the amount of focused substance. The mass analysis unit 51Q sends an analysis result of the measurement to a control apparatus 30E.

The control apparatus 30E includes, in addition to the instruction unit 32 and the notification unit 33, a determination unit 31E. In FIG. 10, the instruction unit 32 and the notification unit 33 is not illustrated. The determination unit 31E determines whether the substrate 5 is abnormal based on an analysis result of the mass analysis sent from the mass analysis unit 51Q.

The determination unit 31E determines whether the substrate 5 is abnormal based on, for example, the detected amount of focused substance or the detected amount per unit time. If the detected amount of focused substance or the detected amount per unit time is larger than a predetermined value, the determination unit 31E determines that the substrate 5 is abnormal. The determination unit 31E sends a determination result whether the substrate 5 is abnormal to the instruction unit 32. If the substrate 5 is determined to be abnormal, like the first embodiment or the second embodiment, the substrate 5 is transported to the coating/developing apparatus 3 or the abnormal substrate recovering mechanism 4 without being subjected to EUV exposure in a vacuum environment.

The mass analysis of the peripheral atmosphere of the substrate 5 may be measured inside the EUV exposure mechanism 20Q, instead of the pressure adjustment mechanism 10Q. FIG. 11 is a diagram showing the configuration of the EUV exposure apparatus according to the fourth embodiment. The same numerals are attached to components, among components in FIG. 11, having the same function as those of the pressure adjustment mechanism 10X or the control apparatus 30A shown in FIG. 1 to avoid a duplicate description.

The EUV exposure mechanism 20Q includes, in addition to the transportation unit 21, the exposure unit 22, and the temperature adjustment unit 25, a mass analysis unit 52Q. The mass analysis unit 52Q conducts a mass analysis of the peripheral atmosphere (inside the EUV exposure mechanism 20Q) of the substrate 5 while the temperature adjustment unit 25 adjusts the temperature of the substrate 5. The mass analysis unit 52Q sends an analysis result of mass analysis to a control apparatus 30F.

The control apparatus 30F includes, in addition to the instruction unit 32 and the notification unit 33, a determination unit 31F. In FIG. 11, the instruction unit 32 and the notification unit 33 is not illustrated. The determination unit 31F determines, like the determination unit 31D, whether the substrate 5 is abnormal based on an analysis result of mass analysis sent from the mass analysis unit 52Q and sends a determination result to the instruction unit 32.

Like the first embodiment or the second embodiment, the substrate 5 whose abnormality in the mass analysis is detected in the pressure adjustment mechanism 10Q or the EUV exposure mechanism 20Q is transported to the coating/developing apparatus 3 or the abnormal substrate recovering mechanism 4 without being subjected to EUV exposure in a vacuum environment.

Thus, a mass analysis is conducted inside the pressure adjustment mechanism 10Q or the EUV exposure mechanism 20Q, and therefore, a residual solvent on the substrate 5, water or component dissolved in water absorbed by the substrate 5, can directly be detected. Consequently, exposing treatment to the substrate 5 can be avoided only when substance that could contaminate the EUV exposure mechanism 1A/1B is present on the substrate 5.

Thus, according to the fourth embodiment, the substrate 5 whose abnormality in the mass analysis is detected in the pressure adjustment mechanism 10Q or the EUV exposure mechanism 20Q is not subjected to EUV exposure in a vacuum environment, and therefore, degradation in reflectance of the optical system 23 and the mask 24 used for EUV exposure can be prevented.

The determination methods or transportation procedures of the substrate 5 described in the first to fourth embodiments may be combined. For example, if a mass analysis of the peripheral atmosphere of the substrate 5 should be conducted in the pressure adjustment mechanism 10Q, an EUV exposure apparatus need to include, at least, an EUV exposure mechanism such as the EUV exposure mechanism 20X. If a mass analysis of the peripheral atmosphere of the substrate 5 should be conducted in the EUV exposure mechanism 20Q, the EUV exposure apparatus need to include, at least, a pressure adjustment mechanism such as the pressure adjustment mechanism 10X.

If, as described in the third embodiment, the degree of vacuum of the peripheral atmosphere of the substrate 5 should be measured in the pressure adjustment mechanism 10Z, the EUV exposure apparatus need to include, at least, an EUV exposure mechanism such as the EUV exposure mechanism 20X. If the degree of vacuum of the peripheral atmosphere of the substrate 5 should be measured in the EUV exposure mechanism 20Z, the EUV exposure apparatus need to include, at least, a pressure adjustment mechanism the pressure adjustment mechanism 10X.

Hereafter, the hardware configuration of the control apparatuses 30A to 30F will be described. The control apparatuses 30A to 30F have similar configurations and thus, the configuration of the control apparatus 30A will be described below.

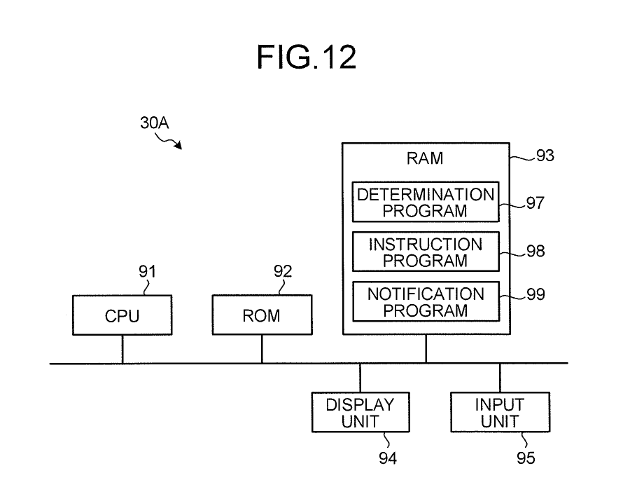

FIG. 12 is a diagram showing a hardware configuration of a control apparatus. The control apparatus 30A includes a CPU (Central Processing Unit) 91, a ROM (Read Only Memory) 92, a RAM (Random Access Memory) 93, a display unit 94, and an input unit 95. In the control apparatus 30A, the CPU 91, the ROM 92, the RAM 93, the display unit 94, and the input unit 95 are connected via a bus line.

The CPU 91 determines whether the substrate 5 is abnormal by using a computer program, namely a determination program 97. The CPU 91 also uses a computer program, namely an instruction program 98, to create instruction information concerning a transportation processing procedure of the substrate 5 or the like and uses a computer program, namely a notification program 99, to create notification information to be sent to the production control system 2 and the coating/developing apparatus 3.

The display unit 94 is a display apparatus such as a liquid crystal monitor and displays the temperature of the substrate 5, a determination result whether the substrate 5 is abnormal, the position of an abnormal substrate, transportation route of an abnormal substrate and the like based on instructions from the CPU 91. The input unit 95 includes a mouse and keyboard, and into which the user inputs instruction information (such as parameters necessary for determining whether the substrate 5 is abnormal) to be input from outside. The instruction information input into the input unit 95 is sent to the CPU 91.

The determination program 97, the instruction program 98, and the notification program 99 are stored inside the ROM 92 and loaded into the RAM 93 via the bus line. FIG. 12 shows a state in which the determination program 97, the instruction program 98, and the notification program 99 are loaded into the RAM 93.

The CPU 91 executes the determination program 97, the instruction program 98, and the notification program 99 loaded into the RAM 93. More specifically, in the control apparatus 30A, the CPU 91 reads the determination program 97, the instruction program 98, and the notification program 99 from inside the ROM 92 according to instruction input from the input unit 95 by the user, and expands the programs into a program storage area inside the RAM 93 to perform various kinds of processing. The CPU 91 causes a data storage area formed inside the RAM 93 to temporarily store various kinds of data generated during the various kinds of processing.

The determination program 97, the instruction program 98, and the notification program 99 executed in the control apparatus 30A are each module-configured including the determination unit 31A and the instruction unit 32 and these are loaded into a main storage apparatus to generate these in the main storage apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing semiconductor devices, comprising:
carrying a substrate coated with a resist film into a first pressure adjustment mechanism;
decompressing a peripheral atmosphere of the substrate from an atmospheric pressure by the first pressure adjustment mechanism;
measuring a physical quantity correlated with an outgassing amount from the substrate;
determining whether to subject the substrate to an EUV exposure based on a measurement result of the physical quantity;
if it has been determined not to subject the substrate to the EUV exposure, transporting the substrate into a second pressure adjustment mechanism without subjecting the substrate to the EUV exposure;
compressing the peripheral atmosphere of the substrate to the atmospheric pressure by the second pressure adjustment mechanism; and
carrying the substrate out of the second pressure adjustment mechanism.

2. The method of manufacturing semiconductor devices according to claim 1, wherein the physical quantity is a temperature of the substrate during the decompression.

3. The method of manufacturing semiconductor devices according to claim 1, wherein the physical quantity is a pressure inside the first pressure adjustment mechanism during the decompression.

4. The method of manufacturing semiconductor devices according to claim 1, wherein the physical quantity is a mass analysis result inside the first pressure adjustment mechanism during the decompression.

5. The method of manufacturing semiconductor devices according to claim 1, wherein the substrate is carried into an EUV exposure mechanism that performs the EUV exposure to make temperature adjustments of the substrate inside the EUV exposure mechanism before being transported into the second pressure adjustment mechanism, and
the physical quantity is a temperature of the substrate while the temperature adjustments are made.

6. The method of manufacturing semiconductor devices according to claim 1, wherein the substrate is carried into an EUV exposure mechanism that performs the EUV exposure to make temperature adjustments of the substrate inside the EUV exposure mechanism before being transported into the second pressure adjustment mechanism, and
the physical quantity is a pressure inside the EUV exposure mechanism while the temperature adjustments are made.

7. The method of manufacturing semiconductor devices according to claim 1, wherein the substrate is carried into an EUV exposure mechanism that performs the EUV exposure to make temperature adjustments of the substrate inside the EUV exposure mechanism before being transported into the second pressure adjustment mechanism, and
the physical quantity is a mass analysis result inside the EUV exposure mechanism while the temperature adjustments are made.

8. The method of manufacturing semiconductor devices according to claim 2, wherein whether to subject the substrate to the EUV exposure is determined based on lowering behavior of the temperature of the substrate during the decompression.

9. The method of manufacturing semiconductor devices according to claim 1, wherein if it has been determined not to perform the EUV exposure, the substrate is transported from the first pressure adjustment mechanism to the second pressure adjustment mechanism without being transported from the first pressure adjustment mechanism into an EUV exposure mechanism that performs the EUV exposure.

10. The method of manufacturing semiconductor devices according to claim 1, wherein if it has been determined not to perform the EUV exposure, the substrate is transported from the first pressure adjustment mechanism into an EUV exposure mechanism that performs the EUV exposure and then, from the EUV exposure mechanism to the second pressure adjustment mechanism.

11. An exposure apparatus, comprising:
a first pressure adjustment mechanism that carries in a substrate coated with a resist film and decompresses a peripheral atmosphere of the substrate from an atmospheric pressure;
a measurement unit that measures a physical quantity correlated with an outgassing amount from the substrate;
a determination unit that determines whether to subject the substrate to an EUV exposure based on a measurement result of the physical quantity;
an exposure unit that subjects the substrate to the EUV exposure by carrying in the substrate from the first pressure adjustment mechanism; and
a second pressure adjustment mechanism that carries in the substrate from the first pressure adjustment mechanism or the exposure unit, compresses the peripheral atmosphere of the substrate to the atmospheric pressure and then, carries the substrate out, wherein
if the determination unit determines not to perform the EUV exposure, the second pressure adjustment mechanism carries the substrate out without the substrate being subjected to the EUV exposure by the exposure unit.

12. The exposure apparatus according to claim 11, wherein the physical quantity is a temperature of the substrate while the peripheral atmosphere of the substrate is decompressed.

13. The exposure apparatus according to claim 11, wherein the physical quantity is a pressure inside the first pressure adjustment mechanism while the peripheral atmosphere of the substrate is decompressed.

14. The exposure apparatus according to claim 11, wherein the physical quantity is a mass analysis result inside the first pressure adjustment mechanism while the peripheral atmosphere of the substrate is decompressed.

15. The exposure apparatus according to claim 11, wherein the exposure unit includes a temperature adjustment unit that adjusts a temperature of the substrate, and
the physical quantity is the temperature of the substrate while the adjustment unit adjusts the temperature of the substrate.

16. The exposure apparatus according to claim 11, wherein the exposure unit includes a temperature adjustment unit that adjusts a temperature of the substrate, and
the physical quantity is a pressure inside the exposure unit while the adjustment unit adjusts the temperature of the substrate.

17. The exposure apparatus according to claim 11, wherein the exposure unit includes a temperature adjustment unit that adjusts a temperature of the substrate, and
the physical quantity is a mass analysis result inside the exposure unit while the temperature adjustment unit adjusts the temperature of the substrate.

18. The exposure apparatus according to claim 12, wherein the determination unit determines whether to subject the substrate to the EUV exposure based on lowering behavior of the temperature of the substrate during the decompression.

19. The exposure apparatus according to claim 11, wherein if the determination unit determines not to perform the EUV exposure, the substrate is transported from the first pressure adjustment mechanism to the second pressure adjustment mechanism without being transported from the first pressure adjustment mechanism into the exposure unit.

20. The exposure apparatus according to claim 11, wherein if the determination unit determines not to perform the EUV exposure, the substrate is transported from the first pressure adjustment mechanism into the exposure unit and then, from the EUV exposure mechanism to the second pressure adjustment mechanism.
